(19) United States
(12) Patent Application Publication
(10) Pub. No.: US 2016/0064624 A1
(43) Pub. Date: Mar. 3, 2016

(54) SEMICONDUCTOR LIGHT EMITTING DEVICE AND LIGHT EMITTING DEVICE PACKAGE

(71) Applicant: SAMSUNG ELECTRONICS CO., LTD., Suwon-si (KR)

(72) Inventors: Chang Bun YOON, Anyang-si (KR); Sang Hyun KIM, Suwon-si (KR); Young Taek KIM, Hwaseong-si (KR); Jae Hyuk LIM, Suwon-si (KR)

(21) Appl. No.: 14/738,730

(22) Filed: Jun. 12, 2015

(30) Foreign Application Priority Data
Aug. 29, 2014 (KR) 10-2014-0114200

(51) Int. Cl. H01L 33/50; H01L 33/32; H01L 25/075; H01L 33/54; H01L 33/56; H01L 33/62; H01L 33/06; H01L 33/58

(52) U.S. Cl. CPC H01L 33/504; H01L 33/06; H01L 33/32; H01L 33/58; H01L 33/54; H01L 33/56; H01L 33/62; H01L 25/0753; H01L 2933/0091

(57) ABSTRACT

A light emitting device package may include: a package board; a semiconductor light emitting device disposed on the package board; and a color characteristics converting unit having a resin including a wavelength conversion material converting light emitted from the semiconductor light emitting device into light of a different wavelength and glass powder having a glass composition with a rare earth element added thereto and filtering light within a particular wavelength band, and disposed on a path on which light emitted from the semiconductor light emitting device travels.

### CROSS-REFERENCE TO RELATED APPLICATION

This application claims priority to Korean Patent Application No. 10-2014-0114200 filed on Aug. 29, 2014, with the Korean Intellectual Property Office, the disclosure of which is incorporated herein by reference.

### BACKGROUND

The present inventive concept relates to a semiconductor light emitting device and a light emitting device package.

A light emitting diode (LED), a type of semiconductor light emitting device, is a semiconductor device capable of generating light of various colors according to recombination of electrons and holes. Semiconductor light emitting devices have various advantages such as relatively long lifespans, low power consumption, excellent initial driving characteristics, and high vibration resistance, and thus, demand for the semiconductor light emitting devices continues to grow. In particular, recently, the utilization of semiconductor light emitting devices has extended to white light sources used in the backlight units of displays and lighting devices, and thus, various attempts have been made to obtain white light being excellent in terms of color rendering or color gamut.

### SUMMARY

An exemplary embodiment of the present inventive concept may provide a semiconductor light emitting device having enhanced light quality and a light emitting device package.

According to an exemplary embodiment of the present inventive concept, a light emitting device package may include: a package board; a semiconductor light emitting device disposed on the package board; and a color characteristics converting unit having a resin including a wavelength conversion material converting light emitted from the semiconductor light emitting device into light of a different wavelength and glass powder having a glass composition with a rare earth element added thereto and filtering light within a particular wavelength band, and disposed on a path on which light emitted from the semiconductor light emitting device travels.

The rare earth element may be at least one selected from the group consisting of neodymium (Nd), erbium (Er), holmium (Ho), praseodymium (Pr), thulium (Tm), and didymium (Di), and may be ion-doped in the glass composition.

The rare earth element may include neodymium (Nd), and neodymium (Nd) may be contained in an amount ranging from 1 mol % to 10 mol % with respect to the overall glass composition including the added rare earth elements.

An average particle size of the glass powder may be 20 um or less.

The glass powder may be 100 parts by weight or less with respect to 100 parts by weight of the resin forming the color characteristics converting unit.

Light within a particular wavelength band filtered by the glass powder may be yellow light.

Light emitted after passing through the color characteristics converting unit may be white light having a color rendering index (CRI) of 90 or greater.

The color characteristics converting unit may further include a light scatterer dispersed in the resin.

The wavelength conversion material may include a red phosphor and a green phosphor.

The color characteristics converting unit may be disposed on the package board to encapsulate the semiconductor light emitting device.

The color characteristics converting unit may include a first resin layer including the wavelength conversion material and a second resin layer disposed on the first resin layer and including the glass powder.

A plurality of semiconductor light emitting devices may be provided, and the plurality of semiconductor light emitting devices may emit light of substantially the same wavelength.

According to another exemplary embodiment of the present inventive concept, a semiconductor light emitting device may include: a light emitting structure including first and second conductivity-type semiconductor layers and an active layer disposed therebetween; and a color characteristics converting unit formed of a resin including glass powder having a glass composition with a rare earth element added thereto and filtering light within a particular wavelength band, and disposed on the light emitting structure.

The color characteristics converting unit may further include a wavelength conversion material converting light emitted from the semiconductor light emitting device into light of a different wavelength.

The color characteristics converting unit may be a thin film having a substantially uniform thickness.

According to another exemplary embodiment of the present inventive concept, a light emitting device package may include a package board; a semiconductor light emitting device disposed on the package board; and a color characteristics converting unit disposed on the semiconductor light emitting device and having a resin structure including a wavelength conversion material converting light emitted from the semiconductor light emitting device into light of a different wavelength and glass powder having a glass composition with a rare earth element added thereto and filtering light within a particular wavelength band. The resin structure may include a mixture of the wavelength conversion material and the glass powder, or include two contiguous layers, of which one layer contains the wavelength conversion material and does not contain the glass powder and the other layer contains the glass powder and does not contain the wavelength conversion material.

The rare earth element may be at least one selected from the group consisting of neodymium (Nd), erbium (Er), holmium (Ho), praseodymium (Pr), thulium (Tm), and didymium (Di), and may be ion-doped in the glass composition.

The rare earth element may include neodymium (Nd). Neodymium (Nd) may be contained in an amount ranging from 1 mol % to 10 mol % with respect to the overall glass composition including the added rare earth elements.

An average particle size of the glass powder may be 20 um or less.

The light converted by the wavelength conversion material may have first and second wavelengths greater than that of the light emitted by the semiconductor light emitting device. A center of the particular wavelength band filtered by the resin structure including the glass powder having the glass composition with the rare earth element may be within a wavelength band from the first wavelength to the second wavelength.

### BRIEF DESCRIPTION OF DRAWINGS

The above and other aspects, features and other advantages of the present inventive concept will be more clearly understood from the following detailed description taken in conjunction with the accompanying drawings, in which:

FIG. 1 is a cross-sectional view illustrating a light emitting device package according to an exemplary embodiment of the present inventive concept;

FIG. 2 is a graph of a spectrum illustrating characteristics of white light according to an exemplary embodiment of the present inventive concept;

FIG. 3 is an experiment graph illustrating light absorption rates over wavelengths of glass powder according to an exemplary embodiment of the present inventive concept;

FIGS. 4A and 4B are cross-sectional views illustrating light emitting device packages according to a modification of FIG. 1;

FIGS. 5A through 5C are cross-sectional views illustrating semiconductor light emitting devices according to an exemplary embodiment of the present inventive concept;

FIGS. 6A and 6B are exploded perspective views illustrating backlight units employing a semiconductor light emitting device or a light emitting device package according to an exemplary embodiment of the present inventive concept;

FIGS. 7 and 8 are a graph and a CIE 1931 color space chromaticity diagram illustrating an improvement effect when a semiconductor light emitting device or a light emitting device package according to an exemplary embodiment is applied to a backlight unit; and

FIGS. 9 and 10 are exploded perspective views illustrating lighting devices employing a semiconductor light emitting device or a light emitting device package according to an exemplary embodiment of the present inventive concept.

### DETAILED DESCRIPTION

Hereinafter, exemplary embodiments of the present inventive concept will be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

Thus, in the drawings, the shapes and dimensions of elements may be exaggerated for clarity, and the same reference numerals will be used throughout to designate the same or like elements. In this disclosure, terms such as “on”, “upper portion”, “upper surface”, “under”, “lower portion”, “lower surface”, “lateral surface”, and the like, are determined based on the drawings, and in actuality, the terms may be changed according to a direction in which a semiconductor light emitting device or a light emitting device package is disposed.

The expression “an exemplary embodiment or one example” used in the present inventive concept does not refer to identical examples and is provided to stress different unique features between each of the examples. However, examples provided in the following description are not excluded from being associated with features of other examples and implemented thereafter. For example, even if matters described in a specific example are not described in a different example thereto, the matters may be understood as being related to the other example, unless otherwise mentioned in descriptions thereof.

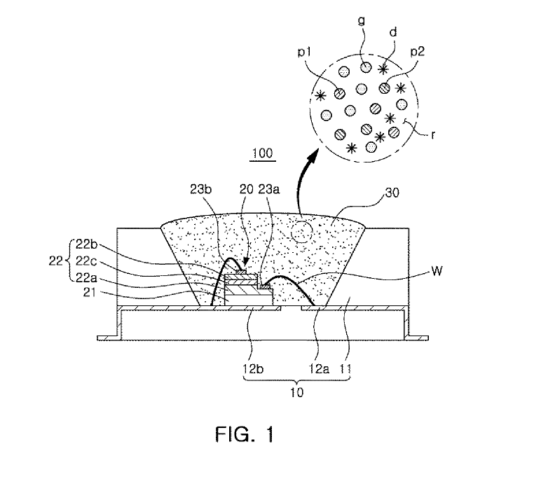

FIG. 1 is a cross-sectional view illustrating a light emitting device package 100 according to an exemplary embodiment of the present inventive concept.

Referring to FIG. 1, the light emitting device package 100 according to the present exemplary embodiment of may include a package board 10, a semiconductor light emitting device 20 disposed on the package board 10, and a color characteristics converting unit 30 disposed on a path on which light emitted from the semiconductor light emitting device 20 travels.

The package board 10 may include a package body 11 and first and second terminal units 12a and 12b.

The package body 11 may serve to support the first and second terminal units 12a and 12b and may be formed of an opaque resin or a resin having a high degree of reflectivity. For example, the package body 11 may be formed of a polymer that can be easily injection-molded. However, the material of the package body 11 is not limited thereto and the package body 11 may be formed of various non-conductive materials.

The first and second terminal units 12a and 12b may be formed of a metal having excellent electrical conductivity, and may be electrically connected to the first and second electrodes 23a and 23b of the semiconductor light emitting device 20 to deliver driving power applied from an external source to the semiconductor light emitting device 20. In the present exemplary embodiment, the first and second terminal units 12a and 12b are illustrated as being connected to the first and second electrodes 23a and 23b using wires w, but the present invention is not limited thereto.

When driving power is applied, the semiconductor light emitting device 20 emits light, and the semiconductor light emitting device 20 may include a substrate 21, a light emitting structure 22, and the first and second electrodes 23a and 23b disposed on the light emitting structure 22.

The substrate 21 may be provided as a substrate for a semiconductor growth, and may be formed of a material having insulating properties and a conductive material such as SiC, MgAl₂O₄, MgO, LiAlO₂, LiGaO₂, or GaN.

The light emitting structure 22 may include first and second conductivity-type semiconductor layers 22a and 22b, and an active layer 22c disposed therebetween. For example, the first and second conductivity-type semiconductor layers may be n-type and p-type semiconductor layers, respectively.

Although not limited thereto, the first and second conductivity-type semiconductor layers 22a and 22b may be formed of materials such as GaN, AlGaN, and InGaN having an empirical formula of AlₓIn_{y}Ga_{(1-x-y)}N, where 0≦x≦1, 0≦y≦1, and 0≦x+y≦1. The active layer 22c formed between the first and second conductivity-type semiconductor layers 22a and 22b may emit light having a predetermined level of energy through recombination of electron-hole pairs and may have a multi-quantum well (MQW) structure in which quantum well layers and quantum barrier layers are alternately stacked, for example, an InGaN/GaN structure.

The first and second electrodes 23a and 23b may be formed on the first and second conductivity-type semiconductor layers 22a and 22b and may be formed of one or more among a known electrically conductive materials, such as Ag, Al, Ni, Cr, Cu, Au, Pd, Pt, Sn, W, Rh, Ir, Ru, Mg, Zn, Ti, or alloys thereof.

The color characteristics converting unit 30 may be formed of a resin r including wavelength conversion materials p1 and p2 and glass powder g, and convert color characteristics of light emitted from the semiconductor light emitting device 20. Here, the wavelength conversion materials p1 and p2 and the glass powder g may be provided in a form of being distributed within the resin r.

If necessary, the color characteristics converting unit 30 may further include light scatterers d dispersed in the resin r. In this case, a proportion of light which fails to be emitted to the outside due to total internal reflection due to a difference in a refractive index between the color characteristics converting unit 30 and an external medium (e.g., air) may be reduced, and light extraction efficiency of the light emitting device package 100 may be increased. The light scatterers d may be formed of a material having a refractive index greater than the material used to form the resin r and may be formed of a material selected from among Al₂O₃, TiO₂, and combinations thereof.

The resin r may be a material selected from among an epoxy, silicone, modified silicone, an urethane resin, an oxetan resin, acryl, polycarbonate, polyimide, and combinations thereof. Since the color characteristics converting unit 30 is formed of the resin r, the color characteristics converting unit 30 may be disposed on the package body 11 to encapsulate the semiconductor light emitting device 20.

The wavelength conversion materials p1 and p2 convert light emitted from the semiconductor light emitting device 20 into light having a different wavelength, and may include at least one among quantum dots and phosphors. If necessary, the color characteristics converting unit 30 may include a plurality of wavelength conversion materials p1 and p2 emitting light having different wavelengths. For example, the wavelength conversion materials p1 and p2 may include at least one phosphor selected from the group consisting of a green phosphor, a yellow phosphor, an orange phosphor, and a red phosphor. Although not limited thereto, light emitted from the semiconductor light emitting device 20 may be ultraviolet radiation, near ultraviolet radiation, or blue light. In an exemplary embodiment, the semiconductor light emitting device 20 emits blue light and the resin (r) forming the color characteristics converting unit 30 may include a green phosphor and a red phosphor as the wavelength conversion materials p1 and p2.

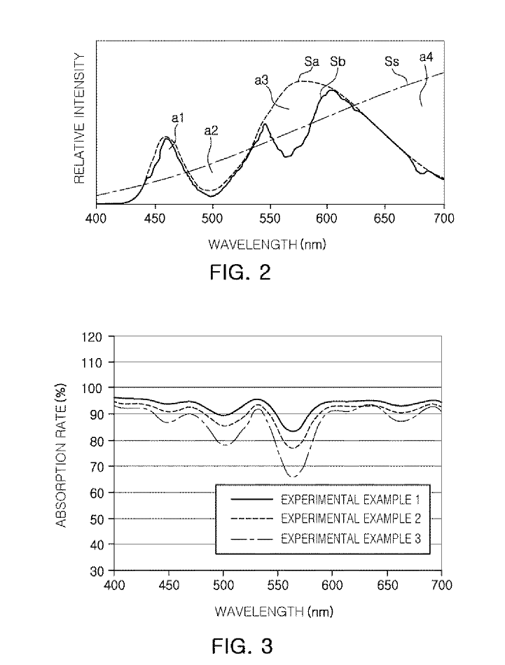

In general, in a case in which the semiconductor light emitting device 20 emitting blue light and green and red phosphors are used as wavelength conversion materials p1 and p2, light ultimately emitted from the light emitting device package 100 may be white light, and a spectrum represented by such white light (hereinafter, referred to as “white light according to the related art example”) may be a spectrum indicated by the dotted line (Sa) illustrated in FIG. 2. The alternate long and short dash line (Ss) illustrated in FIG. 2 represents a spectrum of sunlight having a color temperature equal to 3000K.

As for comparison between the spectrums of white light according to the related art example and sunlight, the spectrum of the white light according to the related art example has regions (a1 and a3) exceeding the spectrum of sunlight in some wavelength bands, and conversely, has regions (a2 and a4) which fall short of the spectrum of sunlight in other wavelength bands. As the degree to which the spectrum of white light according to the related art example deviates from the spectrum of sunlight is greater, white light has a decreased color rendering index. Thus, in order to obtain white light having a high color rendering index with respect to the spectrum of sunlight having a color temperature equal to 3000K, the spectrum of white light emitted needs to be matched to be similar to the spectrum of sunlight having a color temperature equal to 3000K.

To this end, the light emitting device package 100 according to the present exemplary embodiment may include glass powder g that filters light within a particular wavelength band.

Referring back to FIG. 1, the glass powder g may be provided in a distributed manner in the resin r forming the color characteristics converting unit 30.

The glass powder g has a glass composition and a rare earth element may be added to the glass composition.

In an exemplary embodiment, the glass composition of the glass powder g may be a ZnO—BaO—SiO₂—P₂O₅—B₂O₃-based composition and further include at least one alkali or alkali earth element selected from the group consisting of Na₂O, CaO, K₂O, and Li₂O. In this case, since SiO₂ and B₂O₃ are added to the glass composition formed of ZnO, BaO, and P₂O₅, a phase may be more stabilized, and since at least one of the alkali and alkali earth element is added, a glass composition having a low firing temperature (approximately 600° C. or lower) and facilitating a process can be obtained. However, the material of the glass component is not limited thereto, and silicate glass, aluminosilicate glass, borate glass, phosphate glass, plumbate glass, and any other inorganic acid salt glass composition may be used.

A rare earth element may be added to the glass composition. In detail, the rare earth element may be at least one selected from the group consisting of neodymium (Nd), erbium (Er), holmium (Ho), praseodymium (Pr), thulium (Tm), and didymium (Di). For example, the rare earth element may be neodymium (Nd). The rare earth element may be added such that it replaces a certain atom (e.g., silicon (Si)) forming the glass composition and ion-doped in the glass composition.

Although not limited thereto, the glass powder g according to the present exemplary embodiment may be obtained by performing an operation of preparing a mixture in which a source material for obtaining a glass composition and a rare earth oxide are mixed, an operation of sintering the mixture to form a sintered body, and an operation of crushing the sintered body to form the glass powder g. In order to crush the sintered body, a powder crushing process such as milling, or the like, may be applied.

In an exemplary embodiment, SiO₂, B₂O₃, ZnO, and BaO in a powder form as a source material for obtaining a glass composition and Nd₂O₂ powder as a rare earth oxide may be mixed. In the mixture, an appropriate amount of Nd₂O₂ powder may be contained. If the amount of Nd₂O₂ powder is too small, a light filtering effect may be reduced, and if the amount of Nd₂O₂ powder is excessive, solubility of the mixture may exceed an appropriate range. For example, the Nd₂O₂ powder may be mixed in an amount ranging from about 4 wt % to 40 wt % over the overall mixture. Specifically, the Nd₂O₂ powder may be mixed in an amount of ranging from about 10 wt % to 30 wt % over the overall mixture. Although not limited thereto, in this case, the glass powder g obtained by sintering the mixture and subsequently crushing the sintered body may have a BaO—ZnO—SiO₂—B₂O₂-based glass composition and the Nd element may be contained in an amount ranging from about 1 mol % to about 10 mol % with respect to the overall glass composition including the Nd element, specifically, in an amount ranging from about 2.5 mol % to about 7.5 mol %.

FIG. 3 is an experiment graph illustrating light absorption rates over wavelengths of glass powder g according to an exemplary embodiment of the present inventive concept.

In Experimental Example 1, a mixture obtained by mixing a source material for obtaining a glass composition and Nd₂O₃ powder as a rare earth oxide was used, and here, Nd₂O₃ powder was mixed in an amount of 5 wt % over the overall mixture. After the mixture was sintered, a sintered body was crushed to obtain glass powder g, and in this case, in the prepared glass powder g, the Nd element may be contained in an amount of about 1.25 mol % with respect to the overall glass composition including the Nd element.

In Experimental Example 2 and Experimental Example 3, a mixture was obtained in the same manner as that of Experimental Example 1, except that Nd₂O₃ powder was mixed in the amounts of 10 wt % and 20 wt %, respectively. In this case, in the prepared glass powder g, the Nd element may be contained in the amounts of about 2.5 mol % and 5 mol % with respect to the overall glass composition, respectively.

Referring to FIG. 3, it can be seen that glass powder g according to Experimental Example 1 to Experimental Example 3 filter light within a particular wavelength band. In particular, it can be seen that an absorption rate of yellow light of 550 nm to 580 nm band is high, and when the content of Nd is about 5 mol %, an excellent absorption rate can be obtained.

Thus, in the light emitting device package 100 according to the present exemplary embodiment, light emitted from the semiconductor light emitting device 20 and light emitted from the wavelength conversion materials p1 and p2 are mixed to emit white light, and here, the white light may have a spectrum indicated by the sold line Sb illustrated in FIG. 2 by the glass powder g that filters light within a particular wavelength band.

As illustrated in FIG. 2, a region a3 in which the spectrum of white light exceeds the spectrum of sunlight in a wavelength band (for example, the yellow light band) is reduced, compared with the spectrum of white light according to the related art example, and as a degree to which the spectrum of white light agrees with the spectrum of sunlight is enhanced, a color rendering index may be improved. Although not limited thereto, light emitted by being transmitted through the color characteristics converting unit 30 may be white light having a color rendering index equal to or greater than 90.

For example, it was confirmed that when a combination of a semiconductor light emitting device emitting blue light having a dominant wavelength of 445 nm and green and red phosphors respectively emitting dominant wavelengths of 530 nm and 620 nm as wavelength conversion materials is used, the color rendering index was enhanced to a level of 90 or greater. However, the color rendering index is not limited thereto and may differ depending on combinations of wavelength conversion materials. For example, it was confirmed that when a semiconductor light emitting device emitting blue light having a dominant wavelength of 445 nm and a yellow phosphor (e.g., YAG phosphor) are used, a color rendering index was enhanced from 68 to 72 by adding glass powder.

Meanwhile, in a case in which the color characteristics converting unit 30 includes an excessive amount of glass powder g, viscosity of the resin r may be increased. Thus, in consideration of processiblity of the color characteristics converting unit 30, process convenience, and the like, are considered, glass powder g may be contained in an amount of 100 parts by weight or less with respect to 100 parts by weight of resin r forming the color characteristics conversion unit 30. However, the amount of the glass powder g is not limited thereto and may be modified within an appropriate range.

Also, a size of the glass powder g may be selected from within an appropriate range. For example, when it is assumed that glass powder g is contained in the same parts by weight, in a case in which glass powder g having a larger size is applied, an overall surface area thereof may be smaller than that of a case in which glass powder g having a smaller size is applied, and in addition, the glass powder g having a larger size may be difficult to disperse in the resin r. Thus, although not limited thereto, an average particle size of the glass powder g may be 20 um or less. Specifically, in order to obtain excellent filtering efficiency, an average particle size of the glass powder d may range from 1 um to 15 um.

Table 1 shows experimental data illustrating improved effects of the light emitting device package according to an exemplary embodiment.

A light emitting device package of Comparative Example 1A emits white light, and to this end, a semiconductor light emitting device emitting blue light having a dominant wavelength of 445 nm and a combination of green and red phosphors respectively emitting light having dominant wavelengths of 530 nm and 620 nm as wavelength conversion materials were used.

A light emitting device package of Comparative Example 2A had the same components as those of the light emitting device package of Comparative Example 1A, except that a combination of green and red phosphors respectively emitting light having dominant wavelengths of 530 nm and 635 nm were used as wavelength materials. Similarly, a light emitting device package of Comparative Example 3A had the same components as those of the light emitting device package of Comparative Example 1A, except that a combination of green and red phosphors respectively emitting light having dominant wavelengths of 530 nm and 640 nm were used as wavelength materials.

A light emitting device package of Embodiment 1A had the same components as those of the light emitting device package of Comparative Example 1A, except that glass powder was further added in addition to a wavelength conversion material.

TABLE 1

| | Relative | | |
|---|---|---|---|
| | Brightness | CRI | CCT |
| Comparative Example 1A | 100% | 85.2 | 3069 K |
| Comparative Example 2A | 86.2% | 93.3 | 2950 K |
| Comparative Example 3A | 84.6% | 96.8 | 2986 K |
| Embodiment 1A | 94.0% | 91 | 3000 K |

Referring to Table 1, it can be seen that white light emitted from the light emitting device package of Comparative Example 1A has a CRI of 85.2, the lowest. It can be seen that white light emitted from the light emitting device packages of Comparative Example 2A and Comparative Example 3A have CRIs higher than that of the light emitting device package of Comparative Example 1A. This results from a movement of the dominant wavelength of the red phosphor toward a longer wavelength, and when referring to the white light spectrum according to the related art example illustrated in FIG. 2, it is understood as a result of complementation of the region (a4) which falls short of the sunlight spectrum. In this case, however, with respect to the brightness (100%) of white light according to Comparative Example 1A, relative brightness levels thereof were 86.2% and 84.6%, respectively, considerably lower than that of Comparative Example 1A.

Meanwhile, it can be seen that, the CRI of white light emitted from the light emitting device package of Embodiment 1A was lower than that of Comparative Example 2A and Comparative Example 3A but higher than that of the white light of Comparative Example 1A and the relative brightness thereof was 94%, not significantly smaller than that of white light of Comparative Example 1A.

According to the present embodiment, the light emitting device package emitting white light having excellent light quality with the improved CRI and guaranteed sufficient brightness can be obtained.

In addition, the filtering member provided to obtain excellent white light may be dispersed in the form of glass powder in the resin forming the color characteristics converting unit. The color characteristics converting unit may be easily applied to the light emitting device package using a dispensing process, and may be manufactured in various shapes, obtaining excellent processibility.

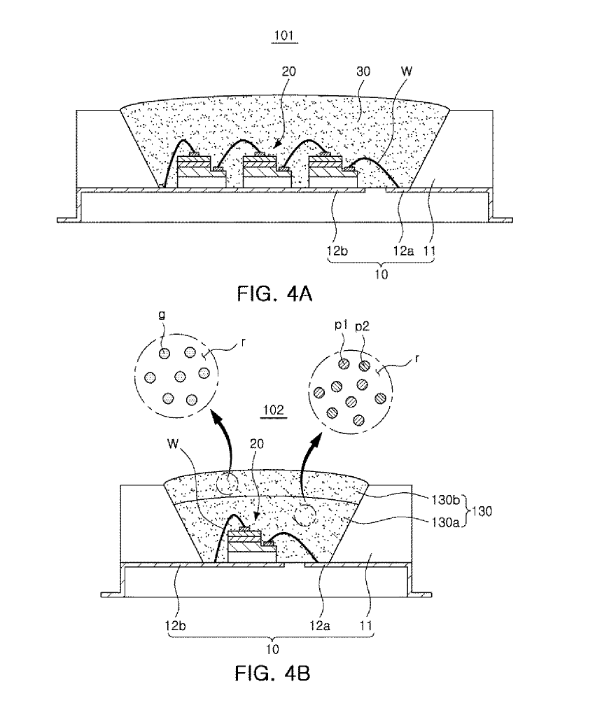

FIGS. 4A and 4B are cross-sectional views illustrating light emitting device packages 101 and 102 according to a modification of FIG. 1. Descriptions of the same components as those of the exemplary embodiment described above will be omitted and different components will be largely described.

Referring to FIG. 4A, the light emitting device package 101 may include a plurality of semiconductor light emitting devices 20. In order to improve a CRI, the plurality of semiconductor light emitting devices 20 may emit blue light, green light, and red light. However, in general, semiconductor light emitting devices emitting blue, green, and red light have different driving voltage characteristics, leading to a problem in that driving power thereof should be controlled separately.

Thus, although not limited thereto, the plurality of semiconductor light emitting devices 20 may be realized to emit light having substantially the same wavelength. For example, all the plurality of semiconductor light emitting devices 20 may be realized to emit ultraviolet light or blue light. In this case, since driving voltage characteristics are substantially the same, there is no need to control driving power of each light emitting device and white light having an improved CRI may be obtained by using the color characteristics converting unit 30 described above in the previous exemplary embodiment.

Referring to FIG. 4B, a color characteristics converting unit 130 may include a first resin layer 130a and a second resin layer 130b disposed on the first resin layer 130a. The first resin layer 130a may include wavelength conversion materials p1 and p2 and may not include glass powder g. Conversely, the second resin layer 130b may include glass powder g and may not include wavelength conversion materials p1 and p2. In this case, first white light is generated by the first resin layer 130a, and when the first white light passes through the second resin layer 130b, it may be converted into second white light having an improved CRI. Thus, the CRI can be effectively improved.

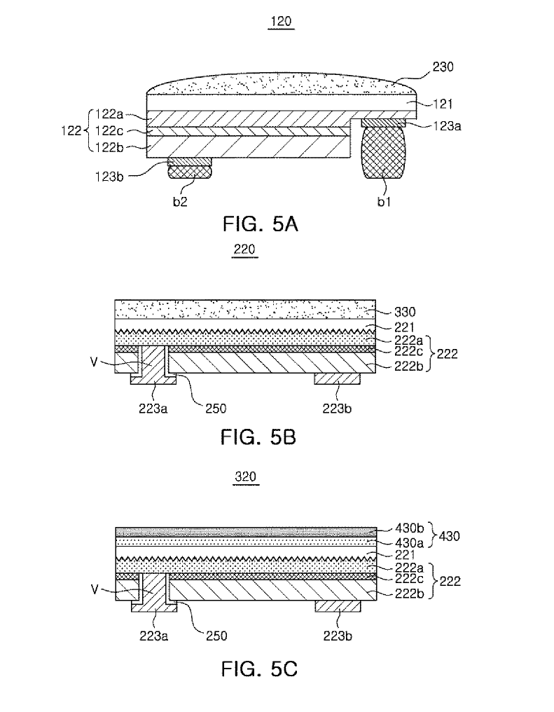

FIGS. 5A through 5C are cross-sectional views illustrating semiconductor light emitting devices 120, 220, and 320 according to an exemplary embodiment of the present inventive concept.

Referring to FIG. 5A, the semiconductor light emitting device 120 may include a substrate 121 and a light emitting structure 122 disposed on the substrate 121. The light emitting structure 122 may include first and second conductivity-type semiconductor layers 122a and 122b and an active layer 122c disposed therebetween. First and second electrodes 123a and 123b may be disposed on the first and second conductivity-type semiconductor layers 122a and 122b, respectively.

A color characteristics converting unit 230 may be disposed on the light emitting structure 122. The color characteristics converting unit 230 may be formed of a resin including wavelength conversion materials and glass powder as those described above.

In the semiconductor light emitting device 120 according to the present exemplary embodiment, an upper surface of the substrate 121 is provided as a main light emitting surface, and thus, the color characteristics converting unit 230 may be disposed on an upper surface of the substrate 121.

In the present exemplary embodiment, the color characteristics converting unit 230 may have a upper surface having a convex meniscus shape, and edges thereof may be defined by the corners of the upper surface of the semiconductor light emitting device 120. For example, in FIG. 5A, the edges of the color characteristics converting unit 230 may be defined by the corners of the upper surface of the semiconductor light emitting device 120, namely, the upper surface of the substrate 121, in contact with the color characteristics converting unit 230.

The convex meniscus shape of the color characteristics converting unit 230 may be obtained using surface tension of the resin forming the color characteristics converting unit 230. Also, the convex meniscus shape may be adjusted using conditions such as viscosity or a thixotropic index of the resin. Viscosity or thixotropic index of the resin may be adjusted by the content and particle size of the glass powder, as well as by the viscosity of the resin itself in use. Viscosity or thixotropic index of the resin may also be adjusted by the content and a particle size of wavelength conversion materials or a light scatterer.

In this case, the color characteristics converting unit 230 may guarantee a uniform distribution of wavelength conversion materials and glass powder, compared with a form molded across the entire region of the light emitting device package or the semiconductor light emitting device. In addition, the convex meniscus upper surface of the color characteristics converting unit 230 provides an advantage in terms of a beam angle of light emitted from the semiconductor light emitting device 120 and chromaticity distribution.

FIGS. 5B and 5C are cross-sectional views illustrating semiconductor light emitting devices 220 and 320 according to an exemplary embodiment of the present inventive concept.

Referring to FIG. 5B, the semiconductor light emitting device 220 includes a substrate 221 and a light emitting structure 222 disposed on the substrate 221. The light emitting structure 222 may include first and second conductivity-type semiconductor layers 222a and 222b and an active layer 222c disposed therebetween. First and second electrodes 223a and 223b may be disposed on the first and second conductivity-type semiconductor layers 222a and 222b, respectively.

In the present exemplary embodiment, the first conductivity-type semiconductor layer 222a has a depression and protrusion pattern formed on a surface thereof, enhancing light extraction efficiency. Also, the first electrode 223a may include a conductive via v electrically connected to the first conductivity-type semiconductor layer 222a by passing through the second conductivity-type semiconductor layer 222b and the active layer 222c. An insulating portion 250 may be positioned on the circumference of the conductive via v in order to electrically insulate the first electrode 223a from the second conductivity-type semiconductor layer 222b and the active layer 222c. A plurality of conductive vias v may be provided and may be arranged in a plurality of rows and columns, for example. In this case, current may be uniformly distributed, enhancing light output of the semiconductor light emitting device 220.

A color characteristics converting unit 330 may be disposed on the light emitting structure 222, and provided as a thin film. For example, the color characteristics converting unit 330 may be separately manufactured as a thin film having a substantially uniform thickness and attached to the semiconductor light emitting device 220. According to the present exemplary embodiment, since the color characteristics converting unit 330 is provided in the form of a thin film, more uniform distribution of wavelength conversion materials and glass powder can be guaranteed, compared with a configuration in which the color characteristics converting unit is molded across the entire region of the light emitting device package of the semiconductor light emitting device.

If necessary, as illustrated in FIG. 5C, a color characteristics converting unit 430 may include a first resin layer 430a and a second resin layer 430b disposed on the first resin layer 430a. The first resin layer 430a may include a wavelength conversion material and may not include glass powder. Conversely, the second resin layer 430b may include glass powder and may not include a wavelength conversion material. In this case, a semiconductor light emitting device 320 having an effectively improved CRI may be obtained.

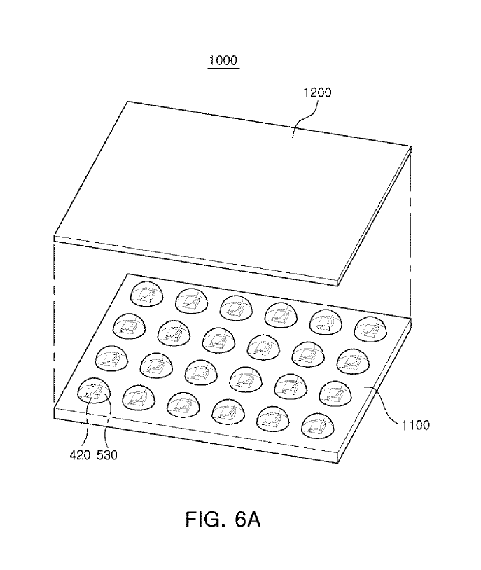

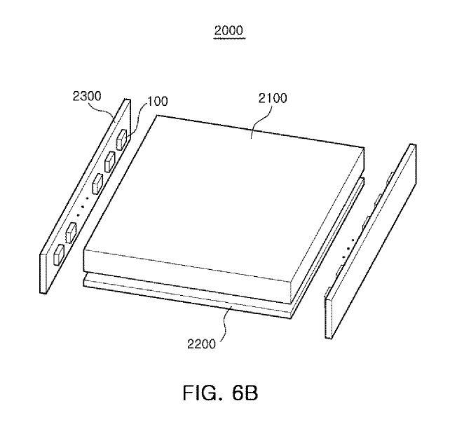

FIGS. 6A and 6B are exploded perspective views illustrating backlight units 1000 and 2000 employing a semiconductor light emitting device or a light emitting device package according to an exemplary embodiment of the present inventive concept.

Referring to FIG. 6A, the backlight unit 1000 may include light sources mounted on a light source board 1100 and one or more optical sheets 1200 disposed above the light source board 1100. The optical sheets 1200 may include a light diffusion plate.

Here, the light sources may be the semiconductor light emitting device or the light emitting device package having the structure described above or a structure similar thereto. As illustrated in FIG. 6A, as for the light sources, a semiconductor light emitting device 420 may be directly mounted as chip-on-board (COB) on the board without a package board. In this case, a color characteristics converting unit 530 may be disposed on the light source board 1100 to cover the semiconductor light emitting device 420.

Unlike the backlight unit 1000 of FIG. 6A in which the light source emits light upwardly in a direction in which a liquid crystal display (LCD) is disposed, a backlight unit 2000 of another example illustrated in FIG. 6B is configured such that a light source mounted on a light source board 2300 emits light in a lateral direction and the emitted light is incident to a light guide plate 2100 so as to be converted into a surface light source. Light passing through the light guide plate 2100 is emitted upwardly, and in order to enhance light extraction efficiency, a reflective layer 2200 may be disposed below the light guide plate 2100. As the light source, the semiconductor light emitting device or the light emitting device package 100 having the structure described above or a structure similar thereto may be used.

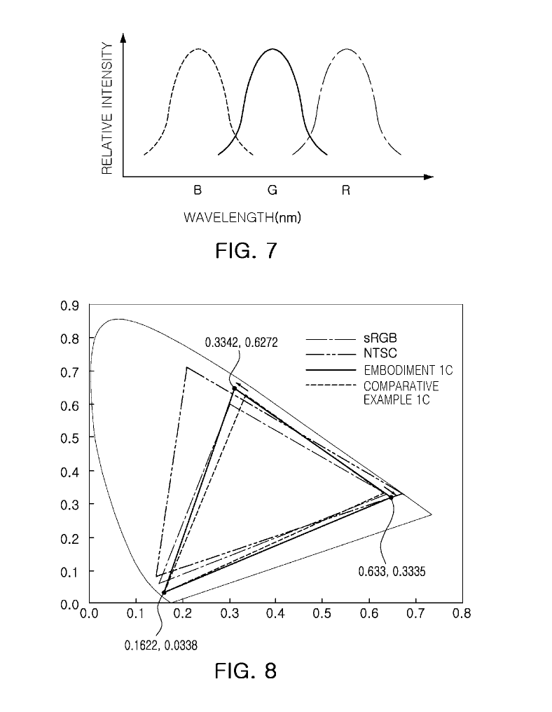

As illustrated in FIG. 7, in order for white light emitted from the backlight unit to have a high color gamut, it may be ideal that white light includes blue, green, and red components having a narrow full width at half maximum (FWHM). In this case, as a light source used in the backlight unit, a scheme of mixing blue, green, and red semiconductor light emitting devices may be considered, but as mentioned above, there is a problem in terms of the controlling thereof, because driving voltage characteristics of the semiconductor light emitting devices are different. Thus, although not limited thereto, in the backlight unit according to the present exemplary embodiment, semiconductor light emitting devices respectively provided in the light sources may be devices emitting light having substantially the same wavelength. For example, a semiconductor light emitting device emitting blue light may be provided. In this case, color characteristics of monochromic light emitted from the semiconductor light emitting device may be converted by the color characteristics converting unit, and thus, white light may be emitted from each light source. The white light is light having a particular wavelength band filtered by the glass powder provided in the color characteristics converting unit, and thus, blue, green, and red colors can be relatively clearly distinguished as the spectrum indicated by the solid line Sb of FIG. 2, improving color gamut.

Table 2 shows experimental data illustrating improved effects in the case that the semiconductor light emitting device or the light emitting device package according to an exemplary embodiment is employed in the backlight unit.

As a light source used in a backlight unit of Comparative Example 1B, a semiconductor light emitting device emitting blue light having a dominant wavelength of 445 nm and a combination of green and red phosphors respectively emitting light having dominant wavelengths of 540 nm and 620 nm were used as wavelength conversion materials.

A light source used in a backlight unit according to Comparative Example 2B had the same components as those of Comparative Example 1B and a combination of green and red phosphors respectively emitting light having dominant wavelengths of 535 nm and 640 nm was used as wavelength conversion materials. Similarly, a light source used in Comparative Example 3A had the same components as those of Comparative Example 1B, except that a combination of green and red phosphors respectively emitting light having dominant wavelengths of 530 nm and 650 nm was used as wavelength conversion materials.

A light source used in a backlight unit of Embodiment 1B had the same components as those of the light source of Comparative Example 1A, except for glass powder further included in addition to the wavelength conversion materials.

TABLE 2

| | Relative | Color gamut |
|---|---|---|
| | brightness | (NTSC area ratio) |
| Comparative Example 1B | 100% | 77.3% |
| Comparative Example 2B | 75% | 85.3% |
| Comparative Example 3B | 71% | 87.4% |
| Embodiment 1B | 85% | 82% |

Referring to Table 2, it can be seen that white light emitted from the backlight unit of Comparative Example 1B has an NTSC area ratio of 77.3%, having the lowest color gamut. It can be seen that, white light of Comparative Example 2B and Comparative Example 3B has NTSC area ratios higher than that of white light of Comparative Example 1B. This is understood as a result of clearly distinguishing blue, green, and red colors by setting a wide dominant wavelength interval between the green phosphor and the red phosphor. In this case, however, relative brightness of Comparative Example 2B and Comparative Example 3B is considerably lower than that of white light of Comparative Example 1B. In contrast, white light of Embodiment 1B has an NTSC area ratio higher than that of Comparative Example 1B and relative brightness which is not considerably low, compared with that of white light of Comparative Example 1B.

FIG. 8 is a CIE 1931 color space chromaticity diagram illustrating an improvement effect when a semiconductor light emitting device or a light emitting device package according to an exemplary embodiment is applied to a backlight unit.

A light source employed in a backlight unit of Comparative Example 1C is a light source emitting white light using a semiconductor light emitting device emitting blue light having a dominant wavelength of 445 nm and a YAG-based phosphor as a yellow phosphor, and a light source employed in a backlight unit of Embodiment 1C is the same as Comparative Example 1C, except that glass powder was used in addition.

Referring to FIG. 8, it can be seen that, white light according to Embodiment 1C is defined by coordinates (0.3342, 0.6272), (0.1622, 0.0338), and (0.633, 0.3335) in the CIE 1931 color space chromaticity diagram and sRGB and NTSC area ratios are 88.88% and 72.01%, respectively. In particular, it can be seen that color gamut in the green and red colors were improved, compared with Comparative Example 1C (please refer to the arrow indication).

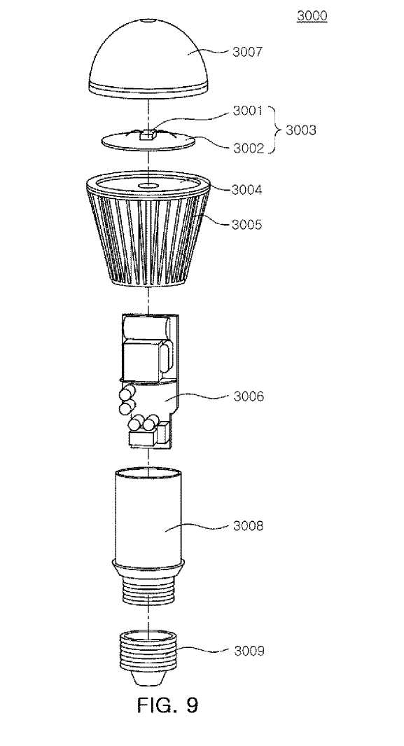

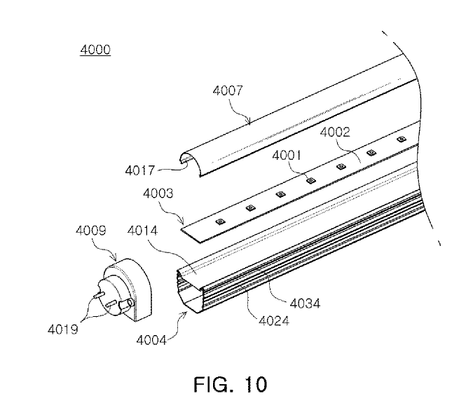

FIGS. 9 and 10 are exploded perspective views illustrating lighting devices 3000 and 4000 employing a semiconductor light emitting device or a light emitting device package according to an exemplary embodiment of the present inventive concept.

The lighting device 3000 is may be a bulb type lamp as illustrated in FIG. 9. Although not limited thereto, the lighting device 3000 may have a shape similar to that of an incandescent light to replace a conventional incandescent light, and may emit light having optical characteristics (a color and a color temperature) similar to those of an incandescent light.

Referring to the exploded perspective view of FIG. 9, the lighting device 3000 includes a light source module 3003, a driving unit 3006, and an external connection unit 3009. Also, the lighting device 3000 may further include external structures such as external and internal housings 3005 and 3008 and a cover unit 3007. The light source module 3003 may include a light source 3001 and a circuit board 3002 on which the light source 3001 is mounted. In the present exemplary embodiment, it is illustrated that a single light source is mounted on the circuit board 3002, but if necessary, a plurality of light sources may be mounted on the circuit board 3002. Here, the light source 3001 may be the semiconductor light emitting device of the light emitting device package described above in the previous exemplary embodiment.

Also, in the lighting device 3000, the light source module 3003 may include an external housing 3005 serving as a heat dissipation unit, and the external housing 3005 may include a heat dissipation plate 3004 disposed to be in direct contact with the light source module 3003 to enhance a heat dissipation effect. Also, the lighting device 3000 may include a cover unit 3007 installed on the light source module 3003 and having a convex lens shape. The driving unit 3006 may be installed in the internal housing 3008 and receive power from an external connection unit 3009 such as a socket structure. Also, the driving unit 3006 may serve to convert received power into an appropriate current source for driving the light source 3001 of the light source module 3003 and provide the same. The driving unit 3006 may include a rectifying unit and a DC/DC converter.

A lighting device 4000 may be a bar-type lamp as illustrated in FIG. 10. Although not limited thereto, the lighting device 4000 may have a shape similar to that of a fluorescent lamp to replace a conventional fluorescent lamp, and may emit light having optical characteristics similar to those of a fluorescent lamp.

Referring to the exploded perspective view of FIG. 10, the lighting device 4000 according to the present exemplary embodiment may include a light source module 4003, a body unit 4004, and a terminal unit 4009. The lighting device 4000 may further include a cover unit 4007 covering the light source module 4003.

The light source module 4003 may include a board 4002 and a plurality of light sources 4001 mounted on the board 4002. The light source 4001 may be the semiconductor light emitting device or the light emitting device package described above in the previous exemplary embodiment.

The body unit 4004 may allow the light source module 4003 to be fixed to one surface thereof. The body unit 4004, a type of support structure, may include a heat sink. The body unit 4004 may be formed of a material having excellent heat conductivity to dissipate heat generated by the light source module 4003 outwardly. For example, the body unit 4004 may be formed of a metal, but the material of the body unit 4004 is not limited thereto.

The body unit 4004 may have an elongated bar-like shape corresponding to the shape of the board 4002 of the light source module 4003 on the whole. A recess 4014 may be formed in one surface of the body unit 4004 on which the light source module 4003 is mounted, in order to accommodate the light source module 4003 therein.

A plurality of heat dissipation fins 4024 may protrude from both outer surfaces of the body unit 4004 to dissipate heat. Stopping recesses 4034 may be formed in both ends of the outer surface positioned in an upper portion of the recess 4014, and extend in a length direction of the body unit 4004. The cover unit 4007 as described hereinafter may be fastened to the stopping recesses 4034.

Both end portions of the body unit 4004 in the length direction thereof may be open, so the body unit 4004 may have a pipe structure with both end portions thereof open. In the present exemplary embodiment, both end portions of the body unit 4004 are open, but the present inventive concept is not limited thereto. For example, only one of the both ends portions of the body unit 4004 may be open.

The terminal unit 4009 may be provided on at least one open side of the both one end portions of the body unit 4004 in the length direction to supply driving power to the light source module 4003. In the present exemplary embodiment, it is illustrated that both end portions of the body unit 4004 are open and the terminal unit 4009 are provided on both end portions of the body unit 4004. However, without being limited thereto, for example, the terminal unit 4009 may only be provided in one open side among both end portions in a structure in which only one side is open.

The terminal unit 4009 may be fastened to both open end portions of the body unit 4004 to cover the same. The terminal unit 4009 may include electrode pins 4019 protruding outwardly.

The cover unit 4007 may be fastened to the body unit 4004 to cover the light source module 4003. The cover unit 4007 may be formed of a material allowing light to be transmitted therethrough.

The cover unit 4007 may have a curved surface having a semicircular shape to allow light to be uniformly irradiated outwardly on the whole. A protrusion 4017 may be formed in a length direction of the cover unit 4007 on the bottom of the cover unit 4007 fastened to the body unit 4004, and engaged with the stopping recess 4034 of the body unit 4004.

In the present exemplary embodiment, the cover unit 4007 has a semicircular shape, but the shape of the cover unit 4007 is not limited thereto. For example, the cover unit 4007 may have a flat quadrangular shape or may have any other polygonal shape. The shape of the cover unit 4007 may be variously modified according to designs of illumination for irradiating light.

As set forth above, according to exemplary embodiments of the present inventive concept, a semiconductor light emitting device or a light emitting device package having improved light quality in terms of CRI or color gamut may be obtained.

While exemplary embodiments have been shown and described above, it will be apparent to those skilled in the art that modifications and variations could be made without departing from the scope of the present invention as defined by the appended claims.

What is claimed is:

1. A light emitting device package comprising:
a package board;
a semiconductor light emitting device disposed on the package board; and
a color characteristics converting unit having a resin including a wavelength conversion material converting light emitted from the semiconductor light emitting device into light of a different wavelength and glass powder having a glass composition with a rare earth element added thereto and filtering light within a particular wavelength band, and disposed on a path on which light emitted from the semiconductor light emitting device travels.

2. The light emitting device package of claim 1, wherein the rare earth element is at least one selected from the group consisting of neodymium (Nd), erbium (Er), holmium (Ho), praseodymium (Pr), thulium (Tm), and didymium (Di), and is ion-doped in the glass composition.

3. The light emitting device package of claim 2, wherein the rare earth element includes neodymium (Nd), and neodymium (Nd) is contained in an amount ranging from 1 mol % to 10 mol % with respect to the overall glass composition including the added rare earth elements.

4. The light emitting device package of claim 1, wherein an average particle size of the glass powder is 20 um or less.

5. The light emitting device package of claim 1, wherein the glass powder is 100 parts by weight or less with respect to 100 parts by weight of the resin forming the color characteristics converting unit.

6. The light emitting device package of claim 1, wherein light within a particular wavelength band filtered by the glass powder is yellow light.

7. The light emitting device package of claim 1, wherein light emitted after passing through the color characteristics converting unit is white light having a color rendering index (CRI) of 90 or greater.

8. The light emitting device package of claim 1, wherein the color characteristics converting unit further includes a light scatterer dispersed in the resin.

9. The light emitting device package of claim 1, wherein the wavelength conversion material includes a red phosphor and a green phosphor.

10. The light emitting device package of claim 1, wherein the color characteristics converting unit is disposed on the package board to encapsulate the semiconductor light emitting device.

11. The light emitting device package of claim 1, wherein the color characteristics converting unit includes a first resin layer including the wavelength conversion material and a second resin layer disposed on the first resin layer and including the glass powder.

12. The light emitting device package of claim 1, wherein a plurality of semiconductor light emitting devices are provided, and the plurality of semiconductor light emitting devices emit light of substantially the same wavelength.

13. A semiconductor light emitting device comprising:
a light emitting structure including first and second conductivity-type semiconductor layers and an active layer disposed therebetween; and
a color characteristics converting unit formed of a resin including glass powder having a glass composition with a rare earth element added thereto and filtering light within a particular wavelength band, and disposed on the light emitting structure.

14. The semiconductor light emitting device of claim 13, wherein the color characteristics converting unit further includes a wavelength conversion material converting light emitted from the semiconductor light emitting device into light of a different wavelength.

15. The semiconductor light emitting device of claim 14, wherein the color characteristics converting unit is a thin film having a substantially uniform thickness.

16. A light emitting device package, comprising:
a package board;
a semiconductor light emitting device disposed on the package board; and
a color characteristics converting unit disposed on the semiconductor light emitting device and having a resin structure including a wavelength conversion material converting light emitted from the semiconductor light emitting device into light of a different wavelength and glass powder having a glass composition with a rare earth element added thereto and filtering light within a particular wavelength band,
wherein the resin structure includes a mixture of the wavelength conversion material and the glass powder, or includes two contiguous layers, of which one layer contains the wavelength conversion material and does not contain the glass powder and the other layer contains the glass powder and does not contain the wavelength conversion material.

17. The light emitting device package of claim 16, wherein the rare earth element is at least one selected from the group consisting of neodymium (Nd), erbium (Er), holmium (Ho), praseodymium (Pr), thulium (Tm), and didymium (Di), and is ion-doped in the glass composition.

18. The light emitting device package of claim 17, wherein the rare earth element includes neodymium (Nd), and neodymium (Nd) is contained in an amount ranging from 1 mol % to 10 mol % with respect to the overall glass composition including the added rare earth elements.

19. The light emitting device package of claim 16, wherein an average particle size of the glass powder is 20 um or less.

20. The light emitting device package of claim 16, the light converted by the wavelength conversion material has first and second wavelengths greater than that of the light emitted by the semiconductor light emitting device, and a center of the particular wavelength band filtered by the resin structure including the glass powder having the glass composition with the rare earth element is within a wavelength band from the first wavelength to the second wavelength.
